(19) United States
(12) Patent Application Publication
(10) Pub. No.: US 2006/0096738 A1
(43) Pub. Date: May 11, 2006

(54) Liquid cold plate heat exchanger

(75) Inventors: Sukhvinder Singh Kang, Rochester, MN (US); John R. Cennamo, Gilford, NH (US)

Correspondence Address: COHEN, PONTANI, LIEBERMAN & PAVANE, 551 FIFTH AVENUE, SUITE 1210, NEW YORK, NY, 10176, US

(73) Assignee: Aavid Thermalloy, LLC

(21) Appl. No.: 11/053,098

(22) Filed: Feb. 8, 2005

Related U.S. Application Data
(60) Provisional application No. 60/625,539, filed on Nov. 5, 2004.

(51) Int. Cl. H05K 7/20

(52) U.S. Cl. 165/80.4; 361/699

(57) ABSTRACT

A heat exchanger includes a cooling plate having a heat collection surface for fixing against an object to be cooled, an opposed heat transfer surface which may be provided with fins, and a cooling chamber over the heat transfer surface, the cooling chamber having an inlet port and an outlet port for circulating a fluid through the cooling chamber via a flow path between the ports. A flow distributor in the flow path forms a plurality of inlet channels communicating with the inlet port, a plurality of outlet channels alternating with the inlet channels and communicating with the outlet port, and a plurality of flow surfaces which are spaced from the heat transfer surface by gaps. The inlet channels communicate with the gaps so that a fluid entering the inlet channels via the inlet port will flow through the gaps, into the outlet channels, and out of the chamber via the outlet port. The gaps are dimensioned to increase fluid velocity and promote mixing of the fluid, thereby improving heat transfer.

### PRIORITY CLAIM

This application claims priority under 35 USC §119 (e) from U.S. provisional application No. 60/625,539 filed Nov. 5, 2004.

### BACKGROUND OF THE INVENTION

1. Field of the Invention

The invention relates to a heat exchanger of the type including a cooling plate having a heat transfer surface and an opposed heat collection surface for fixing against an object to be cooled, and further including a cooling chamber over the heat transfer surface, the cooling chamber having an inlet port and an outlet port for circulating a fluid through the cooling chamber via a flow path between the ports.

2. Description of the Related Art

In conventional liquid cold plate type heat exchangers a fluid is delivered at one end of flow channels and collected at the other end. The fluid typically flows parallel to the surface to be cooled. The channels are laid out in series and parallel paths to manage the fluid path over the cooled surface as a function of fluid preheat (temperature gradient) and acceptable pressure drop. As the fluid channels get narrower, the fluid pressure drop increases. The fluid flow rate has to be kept high to minimize the fluid preheat compared to the temperature difference between the cooled surface and the fluid, which by design limits the heat transfer effectiveness of the cold plate.

In the device disclosed in U.S. Pat. Nos. 5,029,638 and 5,145,001, fluid flows in a direction normal to the surface to be cooled. The fluid is introduced into a plenum above the tips of fins attached to the surface. The fluid enters the flow channels between the fins near the fin tips and exits into fluid collection channels near the base of the fins. The normal flow concept reduces the distance that the fluid travels within the narrow fluid channels between the fins, resulting in low pressure drop. Also, since there is no fluid preheat, this concept allows for high heat transfer effectiveness by design. The weakness of this concept is that the fluid collection channels near the base of the fins interrupt the heat conduction into the fins from the wall from which the fins protrude, i.e. from the heat exchanger plate that is mounted to a heat producing component. This increases the thermal resistance in the heat conduction path to the fins.

### SUMMARY OF THE INVENTION

The heat exchanger according to the invention incorporates a flow distributor in the flow path, the flow distributor including a plurality of inlet channels communicating with the inlet port, a plurality of outlet channels alternating with the inlet channels and communicating with the outlet port, and a plurality of flow surfaces which are spaced from the heat transfer surface by gaps. The inlet channels communicate with the gaps so that a fluid entering the inlet channels via the inlet port will flow through the gaps, into the outlet channels, and out of chamber via the outlet port.

In operation, fluid enters the inlet port of the cold plate and flows into the inlet section that connects all the inlet channels of the flow distributor. The inlet channels direct the fluid into gaps adjacent to the cooling plate. The fluid flows over and exchanges heat with the heat transfer surface for a short distance before entering the outlet channels and exiting the outlet section via the outlet port.

While fluid flows through the cold plate at relatively low velocities in regions with low flow resistance, such as the inlet section and outlet section, it flows at a relatively high velocities through the gaps, where the high flow resistance enhances heat transfer in the region of the surface to be cooled. This enables a low-pressure drop to be achieved while allowing very high heat transfer coefficients on the cooled surface.

The new distributed flow impingement and collection concept enables high performance cold plates to be formed using a variety of enhanced heat transfer structures. The concept is suitable for both single-phase and two-phase cold plates. Advantages of the heat exchanger according to the invention include the following:
High heat transfer performance can be achieved with heat transfer surfaces that have meso and micro scale extended surfaces (fins) and/or other heat transfer enhancement structures (flow interruptions, roughness, dimples etc):
cooling fluid is distributed directly to many locations on the surface to be cooled, which minimizes the amount of fluid preheat and maximizes efficiency;
fluid is collected close to the location where it was delivered, which limits the length of the fluid flow path and keeps the pressure drop low;
high heat transfer performance is achieved with low fluid pressure drop;
the size of the cooled surfaces can easily be scaled to larger sizes while maintaining the ability to deliver the same cooling capability per unit surface area;
surfaces with non-uniform heat fluxes can be managed at a lower net flow rate of fluid by impinging a correspondingly designed non-uniform fluid flux to the surface.

The heat exchanger according to the invention can be used effectively on bare surfaces as well as on any type of enhanced heat transfer surfaces (fins, grooves, dimples, etc.). It can be used with well structured surface enhancements such as uniform arrays of plate fins, grooves, pin fins, interrupted plate fins, and cross-cut fins, as well as random enhancements such as roughness elements, knurling, dendrites, porous foams, and porous sintered powders.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

FIG. 1 is an exploded top perspective view of a first embodiment of heat exchanger according to the invention;

FIG. 1A is a perspective view of an alternative cooling plate;

FIG. 2 is an exploded bottom perspective view of the cover and flow distributor module of the first embodiment;

FIG. 3 is a section view of the heat exchanger of FIGS. 1 and 2;

FIG. 4 is an exploded perspective view of a second embodiment of heat exchanger according to the invention;

FIG. 5 is a section view of the heat exchanger of FIG. 4;

FIG. 6 is a side view of a third embodiment of heat exchanger;

FIG. 7 is a plan view of the third embodiment without the cover; and

FIG. 8 is a plan view of the cooling plate of the third embodiment.

### DETAILED DESCRIPTION OF THE PRESENTLY PREFERRED EMBODIMENTS

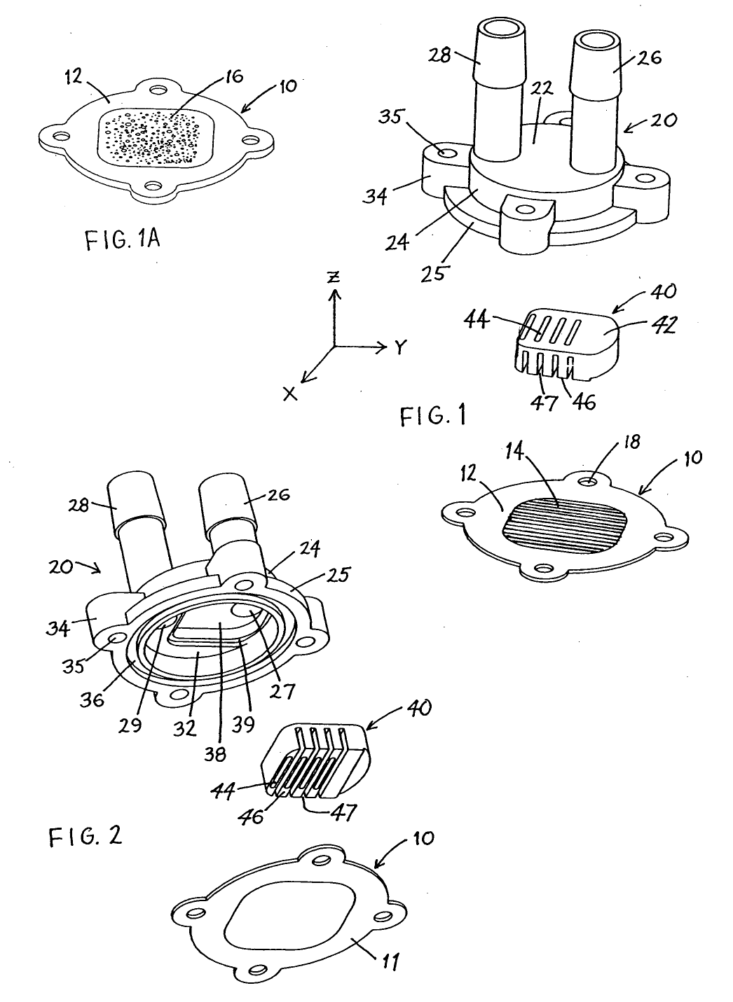

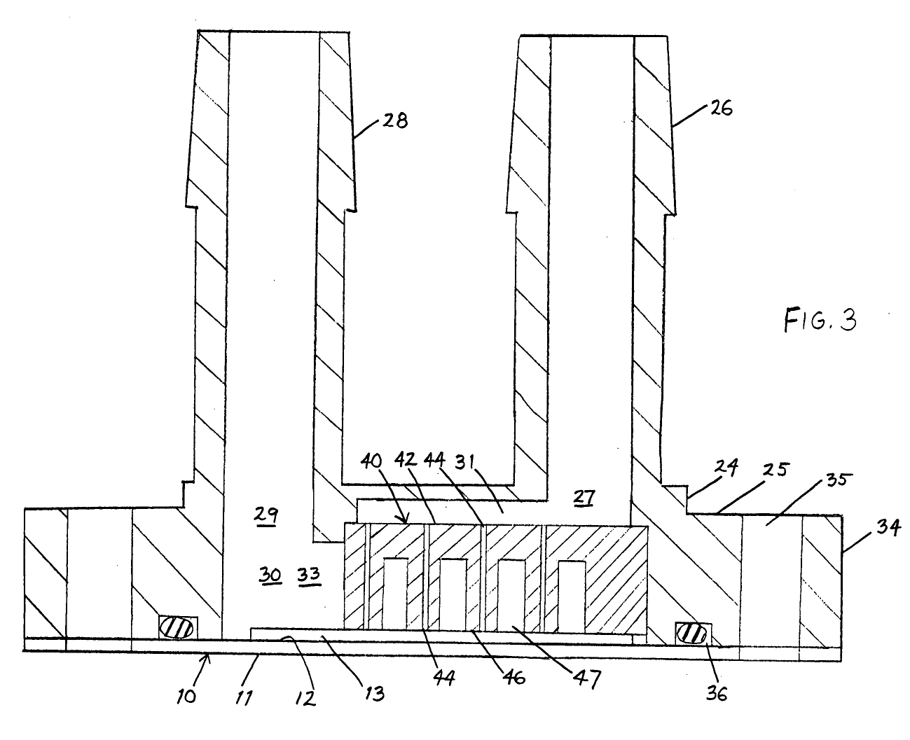

Referring to FIGS. 1 and 2, a first embodiment of the heat exchanger according to the invention includes a metal cooling plate 10 having a heat collection surface 11 for mounting against an object to be cooled, such as a semiconductor component, and an opposed heat transfer surface 12 against which fluid is circulated to remove heat. The heat transfer surface 12 is provided with an array of parallel microfins 14 upstanding from the surface 12. These fins may be formed by rolling grooves into the plate 10 and thus may have a height of as little as 0.001 in. or less. According to an alternative embodiment, shown in FIG. 1A, the heat transfer surface is provided with a random surface enhancement in the form of a porous foam pad 16. A cover 20, which is fitted over the cooling plate 10, has a top 22 provided with an inlet nipple 26 and an outlet nipple 28 for connecting fluid conduits to circulating means such as a pump, and is surrounded by a circumferential wall 24 and a mounting base 25. The base 25 is provided with a sealing groove 36 for receiving a rubber O-ring, as well as bosses 34 and mounting holes 35 which match mounting holes 18 in the cooling plate 10. The cover 20 is provided with a first recess 32 and a second recess 38 formed in the bottom of the first recess 32 for receiving a flow distributor 40. When fitted to the cooling plate 10, the recesses form a cooling chamber 30. The distributor 40 is preferably a molded plastic module which is fixed in the second recess 38 and spaced from the bottom of the second recess by a shoulder 39 to form an inlet section 31 of the chamber 30 (FIG. 3). An inlet port 27 in the bottom of the second recess 38 communicates with the inlet nipple 26. An outlet port 29 located in the bottom of the first recess 32 but outside the second recess 32 communicates with the outlet nipple 28. As an alternative to the second recess 38, the flow distributor 40 may be provided with a recess which forms the inlet section 31.

Referring also to FIG. 3, the flow distributor 40 serves as a dividing wall between the inlet section 31 and the outlet section 33 of the cooling chamber 30. This dividing wall is provided with parallel slots 44 extending between the inlet section 31 and the outlet section 33, thereby serving as inlet channels leading to the outlet section. The dividing wall 40 has a plurality of coplanar lands 46 which are separated by outlet channels 47 and are spaced from the heat transfer surface by gaps 48. Each land 46 is interrupted by a respective slot or inlet channel 44 to form flow surfaces facing the heat transfer surface 12.

When the heat transfer plate is provided with fins 14, the lands 46 are preferably in contact with the tops of the fins, so that the height of the fins determines the size of the gap. This forces the cooling fluid in the gap 48 to flow through channels between the fins, which increases the flow velocity and causes the fluid to change directions several times as it moves in a general direction toward outlet port 29. Using rectangular coordinates as shown in FIG. 1 for convenience, the fluid first travels downward through the slots 44 in the Z-direction, then through the gaps 48 in the Y-direction, then through the outlet channels 47 in the X-direction.

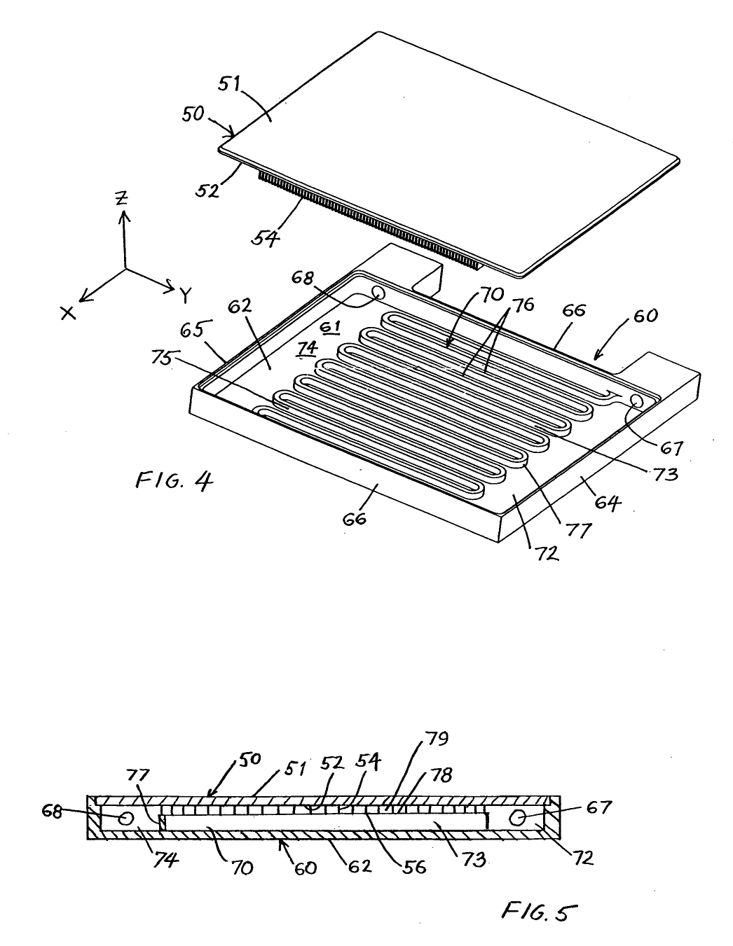

A second embodiment of heat exchanger according to the invention is shown in FIGS. 4 and 5. The cooling plate 50 has a heat collection surface 51, a heat transfer surface 52, and microfins 54 on the heat transfer surface. The cover 60 has a base 62, as well as a front wall 64, a rear wall 65, and opposed sidewalls 66 upstanding from the edges of the base. The cover 60 is fitted to the cooling plate 50 to form a cooling chamber 61, and may be fixed by brazing (where both components are metal), adhesive bonding, or mechanical fixing with a gasket.

The flow distributor is formed by a serpentine wall 70 fixed to the base 62 and extending between the sidewalls 66, thereby dividing the cooling chamber 61 into an inlet section 72 supplied by inlet port 67 and an outlet section 74 which supplies outlet port 68. The serpentine wall 70 forms inlet channels 73 in the inlet section 72, and outlet channels 75 in the outlet section 74, wherein the inlet channels 73 alternate with the outlet channels 75. The wall 70 has parallel wall sections 76 joined by bights 77 which form closed ends of the inlet channels 73 and outlet channels 75. While the wall sections 76 are shown as parallel, this is not essential; the wall may be sinusoidal or any other shape providing alternating inlet and outlet channels. Likewise the closed ends 77 of the channels 73, 75 need not be curved but may be squared off to mate with the fins, as will be described.

The serpentine wall 70 has a lengthwise edge 78 which is spaced from the heat transfer surface 52 by a gap 79 when the cooling plate 50 is fixed to the cover 60 to close the chamber 61. Where the heat transfer surface is provided with fins 54, which are shown with an exaggerated height dimension in cross section of FIG. 5, the tips 56 of the fins 54 are preferably in direct contact with the top of wall 70. The height of the fins 56 therefore defines the size of the gaps 79 between the flow surfaces formed on the wall sections 76 and the surface 52, so that all fluid must pass through the channels 58 between the fins. This arrangement, like the arrangement of the first embodiment, also results in multi-directional fluid flow having a high velocity in the gaps 79. Using the rectangular coordinates shown in FIG. 4, the fluid enters the inlet port 67 in the X-direction, enters the inlet channels 73 in the Y-direction, passes through the gaps 79 in the X-direction, moves through the outlet channels 75 in the Y-direction, and exits the outlet port 68 in the X-direction. Naturally there is also considerable mixing in the Z-direction as the fluid moves into and out of the high velocity region in the gaps, which mixing results in improved heat transfer. Additional mixing in the Z-direction results where the inlet and outlet ports 67, 68 are provided in the base 62, space permitting.

It is worth emphasizing that the advantages of the invention may be realized without the fins provided on the heat transfer surface of the cooling plate, but the fins add additional surface area for heat dissipation to the plate and also serve to direct and mix the fluid.

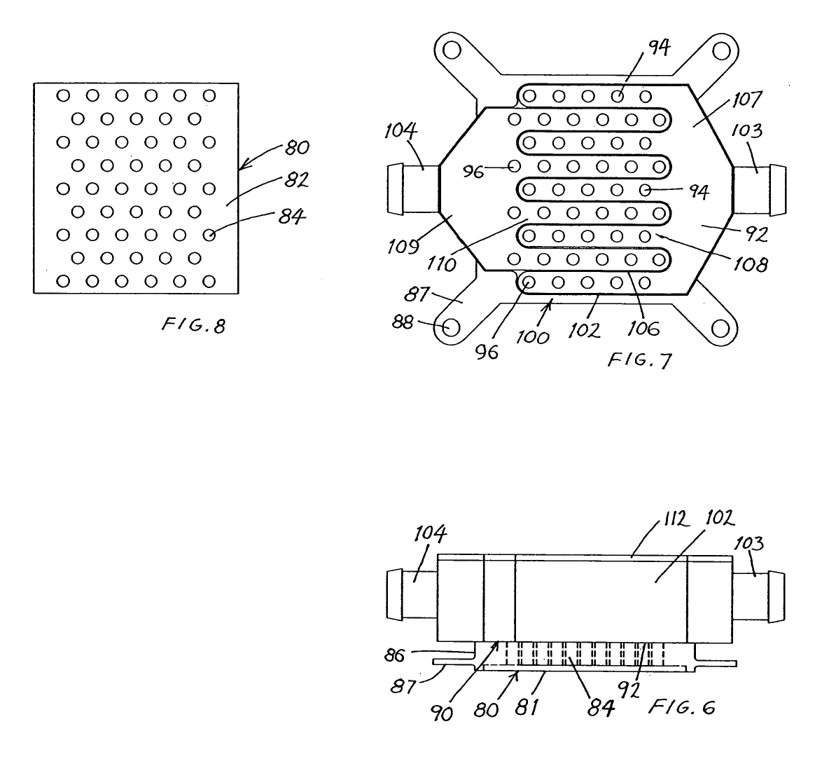

FIGS. 6-8 show an embodiment of heat exchanger utilizing a pin fin type cooling plate 80, a flow distributor 90, and a manifold 100. The cooling plate 80 includes a heat collecting surface 81 and a heat transfer surface 82 provided with pin fins 84, and is fitted in a circumferential wall 86 to form a cooling chamber around the pin fins 84. The wall 86 is provided with tabs 87 having mounting holes 88 for fixing the plate 80 over a component to be cooled, for example a semiconductor on a PCB. The flow distributor 90 includes a base plate 92 having rows of inlet holes 94 alternating with rows of outlet holes 96. The manifold 100 includes a circumferential wall 102 having an inlet nipple 103 and an outlet nipple 104 for connecting to a circulation loop, and a serpentine dividing wall 106 separating an inlet section 107 with inlet channels 108 from an outlet section 109 with outlet channels 110. The inlet channels 108 alternate with the outlet channels 110 and communicate with respective rows of inlets holes 94 and outlet holes 96. The base plate 92 is preferably placed directly on top of the pin fins 84 with the inlet holes 94 (five holes per row) aligned with spaces between the pin fins 84 of odds rows (six pins per row) and the outlet holes 96 (six holes per row) aligned with spaces between pin fins 84 of the even rows (five pins per row). This creates an essentially downward wash of cooling fluid over some pin fins and an essentially upward wash over other pin fins, as well good mixing when the fluid changes directions against the heat transfer surface 82. The cover 112 is fitted flush against the top of the serpentine wall 106 so that fluid flows from the inlet 107 to the outlet section 109 exclusively via the cooling chamber surrounding the pin fins 84.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A heat exchanger for removing heat from an object to be cooled, said heat exchanger comprising:
a cooling plate having a heat transfer surface and an opposed heat collection surface for fixing against an object to be cooled;
a cooling chamber over said heat transfer surface, said cooling chamber having an inlet port and an outlet port for circulating a fluid through said cooling chamber via a flow path between said ports; and
a flow distributor in said flow path, said flow distributor comprising a plurality of inlet channels communicating with said inlet port, a plurality of outlet channels alternating with said inlet channels and communicating with said outlet port, and a plurality of flow surfaces which are spaced from said heat transfer surface by gaps, said inlet channels communicating with said gaps so that a fluid entering said inlet channels via said inlet port will flow through said gaps, into said outlet channels, and out of said chamber via said outlet port.

2. The heat exchanger of claim 1 wherein said flow surfaces are substantially coplanar and are parallel to said heat transfer surface, whereby said gaps are uniform.

3. The heat exchanger of claim 2 wherein said cooling plate comprises structured surface enhancements on said heat transfer surface.

4. The heat exchanger of claim 3 wherein said structured surface enhancements comprise a plurality of cooling fins upstanding from said heat transfer surface and into said gaps.

5. The heat exchanger of claim 4 wherein said cooling fins are substantially parallel and extend transversely of said inlet channels.

6. The heat exchanger of claim 5 wherein said fins are in contact with said flow surfaces, whereby fluid is forced to flow through said gaps transversely to flow in said inlet and outlet channels.

7. The heat exchanger of claim 1 wherein said cooling plate comprises random surface enhancements on said heat transfer surface.

8. The heat exchanger of claim 7 wherein said random surface enhancements are formed by a foam pad fixed to said heat transfer surface.

9. The heat exchanger of claim 1 wherein the flow distributor comprises a dividing wall which divides said chamber into an inlet section and an outlet section, said inlet section being isolated from said heat transfer surface by said dividing wall, said inlet channels comprising a plurality of slots extending through said dividing wall from said inlet section to said outlet section, said dividing wall having a plurality of lands spaced from said heat transfer surface by said gaps and separated by said outlet channels, each said land being interrupted by a respective said slot so that said flow surfaces are formed on said lands.

10. The heat exchanger of claim 9 further comprising a cover fitted to said cooling plate to form said chamber, said inlet port and said outlet port being formed in said cover, said flow distributor being formed as a module which is fitted over said inlet port, one of said module and said cover being formed with a recess which forms said inlet section.

11. The heat exchanger of claim 10 wherein said recess is provided in said cover, said module being received in said recess.

12. The heat exchanger of claim 1 wherein said flow distributor comprises a serpentine wall which divides said chamber into an inlet section comprising said inlet channels and an outlet section comprising said outlet channels, both said inlet section and said outlet section interfacing with said heat transfer surface, said serpentine wall having a lengthwise edge which is spaced from said heat exchange surface by said gaps and thereby forms said flow surfaces.

13. The heat exchanger of claim 12 wherein said serpentine wall comprises substantially parallel wall sections connected by bights which form closed ends of said channels.

14. The heat exchanger of claim 12 further comprising a cover fitted to said cooling plate to form said chamber, said cover comprising a base and a pair of opposed sidewalls, said serpentine wall extending between said sidewalls and extending upward from said base so that said lengthwise edge is spaced from heat transfer surface by said gap.

15. A heat exchanger for removing heat from an object to be cooled, said heat exchanger comprising:
a cooling plate having a heat transfer surface and an opposed heat collection surface for fixing against an object to be cooled, said heat transfer surface having structured surface enhancements;
a cooling chamber over said heat transfer surface, said cooling chamber having rows of inlet holes and rows of outlet holes, said rows of inlet holes alternating with said rows of outlet holes; and
a manifold comprising an inlet section communicating with said inlet holes and an outlet section communicating with said outlet holes.

16. The heat exchanger of claim 15 wherein said manifold comprises a serpentine dividing wall which separates said inlet section from said outlet section, said inlet section having a plurality of inlet channels which communicate with said inlet holes, said outlet section having a plurality of outlet channels which communicate with said outlet holes, said inlet channels communicating with said outlet channels.

17. The heat exchanger of claim 15 wherein said structured surface enhancements stand upright from said heat transfer surface.

18. The heat exchanger of claim 17 wherein said structured surface enhancements consist of pin fins.

19. The heat exchanger of claim 18 wherein said pin fins are in rows which are aligned with respective rows of pin fins.
